(19) United States
(12) Patent Application Publication
(10) Pub. No.: US 2009/0096023 A1
(43) Pub. Date: Apr. 16, 2009

(54) METHOD FOR MANUFACTURING SEMICONDUCTOR DEVICE

(76) Inventor: Yong-Soo Cho, Gangnam-gu (KR)

Correspondence Address: SHERR & VAUGHN, PLLC, 620 HERNDON PARKWAY, SUITE 200, HERNDON, VA, 20170, US

(21) Appl. No.: 12/238,522

(22) Filed: Sep. 26, 2008

(30) Foreign Application Priority Data
Oct. 11, 2007 (KR) 10-2007-0102447

(51) Int. Cl. H01L 29/78; H01L 21/336

(52) U.S. Cl. 257/344; 438/300; 257/E29.266; 257/E21.437

(57) ABSTRACT

A method for manufacturing a semiconductor device that eliminates the cause of increase in leakage current and therefore suppresses power increase in a highly integrated circuit by forming a shallow junction using a dopant-containing oxide film after etching a semiconductor substrate in source and drain regions.

The present application claims priority under 35 U.S.C. 119 to Korean Patent Application No. 10-2007-0102447 (filed on Oct. 11, 2007), which is hereby incorporated by reference in its entirety.

### BACKGROUND

Generally, a metal oxide silicon field effect transistor (MOSFET) has a structure in which a gate electrode and source/drain electrodes are formed on and/or over a silicon substrate, with a dielectric layer disposed therebetween. Recently, as semiconductor devices have become more highly integrated or otherwise miniaturized, lightweight and thin, the physical size of the MOSFET is scaled down, thereby decreasing a valid channel length and causing a short channel effect deteriorating a punch-through between a source and a drain. To resolve such problems, an LDD structure using a shallow junction in the source and drain of the MOSFET has appeared.

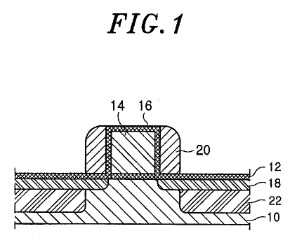

As illustrated in example FIG. 1, a method for manufacturing a MOSFET structure of a semiconductor device may include forming a device isolation and well in silicon substrate 10 as a semiconductor substrate, forming gate dielectric layer 12 on and/or over the entire surface of substrate 10. Doped polysilicon is then deposited on and/or over gate dielectric layer 12 and then patterned to thereby form gate electrode 14. A silicon oxide film SiO2 as buffer dielectric layer 16 may then be thinly formed on and/or over the entire surfaces of gate dielectric layer 12 and gate electrode 14. Thin LDD junction layer 18 into which a low-concentration impurity (n⁻/p⁻) is implanted is then formed in substrate 10 at both sides of gate electrode 14 by carrying out an LDD ion implantation process. Spacers 20 composed of a dielectric material such as a silicon nitride film Si₃N₄, may then be formed on and/or over sidewalls of buffer dielectric layer 16 of gate electrode 14. Source/drain junction layer 22 into which a high-concentration impurity (n⁺/p⁺) is implanted may then be formed in substrate 10 at both sides of spacers 20 by carrying out a source/drain ion implantation process. The MOSFET thus manufactured has source/drain junction layer 22 of LDD 18 structure between the channels of the surface of substrate 10. Gate electrode 14 having conductivity is provided on and/or over LDD junction layer 18, with gate dielectric layer 12 disposed therebetween, and spacers 20 made of a dielectric material is formed on and/or over sidewalls of gate electrode 14.

However, in the semiconductor device having a MOSFET structure as described above, with requirements for high integration of less than 65 nm, as the depth of a shallow junction increases due to the limitations of an ion implantation process in such a MOSFET, a short channel effect increases. Therefore, an increase in leakage current off occurs. This is the direct cause of an increase in power in a product with an increased direct access.

### SUMMARY

Embodiments relate to a method for manufacturing a semiconductor device having a lightly doped drain (LDD) structure, and more particularly, to a method for forming a thin shallow junction using a dopant-containing oxide film.

Embodiments relate to a method for manufacturing a semiconductor device which eliminates the cause of increase in leakage current off, and therefore, suppress power increase in a highly integrated circuit by forming a shallow junction by use of a dopant-containing oxide film after etching a semiconductor substrate in source and drain regions.

Embodiments relate to a method for manufacturing a semiconductor device that may include at least one of the following steps: forming a side wall oxide film on and/or over each side of a gate formed on and/or over a semiconductor substrate; and then forming a spacer on and/or over each side of the gate by using a nitride film; and then removing a portion of the semiconductor substrate to a predetermined depth by performing an etching process using the spacer as a mask and then forming a dopant-containing oxide film on and/or over the semiconductor substrate, the sidewall oxide film and the spacer; and then forming a shallow junction by diffusing the dopant into the semiconductor substrate by performing a thermal process; and then forming a source and a drain on and/or over the semiconductor substrate where the shallow junction is formed.

Embodiments relate to a method that may include at least one of the following steps: forming a gate over a substrate; and then forming a first oxide film over the substrate including uppermost surface and sidewalls of the gate; and then forming a nitride spacer over sidewalls of the gate including the first oxide film; and then forming a stepped portion of the substrate by removing portions of the substrate such that substrate includes a first substrate portion upon which the gate is formed and a second substrate portion provided laterally below the first substrate portion at a predetermined distance; and then forming a doped second oxide film over the entire surface of the first and second portions of the substrate including the gate; and then simultaneously forming a shallow junction under the gate and removing the doped second oxide film by performing a thermal process; and then forming source and drain regions over the shallow junction.

Embodiments relate to a semiconductor device that may include at least one of the following: a polysilicon gate formed over a semiconductor substrate; an oxide film formed over sidewalls of the polysilicon gate; a spacer formed over sidewalls of the oxide film; a shallow junction formed in the semiconductor substrate by diffusing a dopant into the semiconductor substrate; and a source and a drain formed over the shallow junction.

In accordance with embodiments, the sidewall oxide film has a thickness in a range between approximately 4 to 6 nm. The nitride film has a thickness in a range between approximately 18 to 22 nm. The predetermined depth may be in a range between approximately from 18 to 22 nm. The dopant-containing oxide film is formed by using a CVD. The dopant is phosphorous (P) in case of N-MOS device, and boron (B) in case of P-MOS device. The thermal process is carried out in a range between approximately 25 to 35 minutes within a temperature in a range between approximately 800 to 1000° C.

Embodiments can eliminate the cause of increase in leakage current off and therefore suppress power increase in a highly integrated circuit by forming a shallow junction by use of a dopant-containing oxide film after etching a semiconductor substrate in source and drain regions. Furthermore, embodiments can maximize the integrity of an SRAM bit-cell size or the like and obtain a process allowance by minimizing a spacer width by manufacturing a MOSFET through a process of forming a shallow junction by use of a dopant-containing oxide film.

### DRAWINGS

Example FIG. 1 illustrates a MOSFET structure of a semiconductor device.

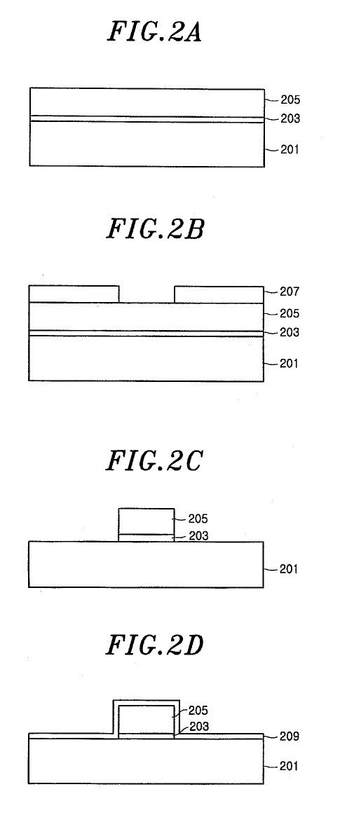

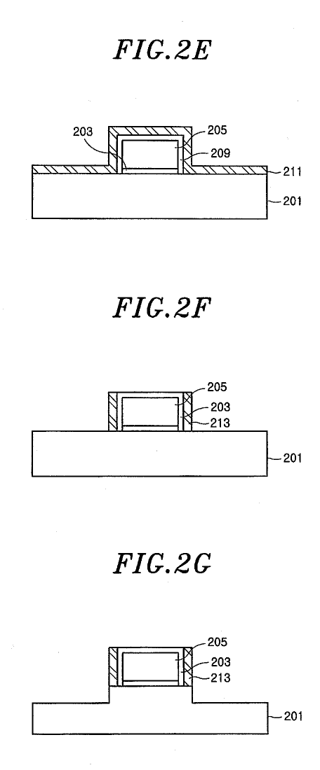

Example FIGS. 2A to 2J illustrate a method for manufacturing a semiconductor device in accordance with embodiments.

### DESCRIPTION

As illustrated in example FIG. 2A, device isolation and well formation are carried out in semiconductor substrate (P-substrate) 201, for example, a silicon substrate. Gate oxide film 203 and polysilicon layer 205 may then be sequentially formed on and/or over substrate 201. Polysilicon layer 205 is preferably formed at a thickness in a range between approximately 120 to 150 nm.

As illustrated in example FIG. 2B, PR pattern 207 for defining a poly gate region may then be formed on and/or over polysilicon layer 205 by selectively removing a portion of a photoresist (PR) coated on and/or over the entire surface of polysilicon layer 205 by an exposure and development process using a recticle designed in a certain target pattern.

As illustrated in example FIG. 2C, a poly gate including gate 205 and an underlying gate oxide 203 may then be formed by selectively removing the gate oxide film and the polysilicon layer by an etching process (e.g., a dry method) using PR pattern 207 as a mask. The remaining PR pattern 207 is then removed by a stripping process.

As illustrated in example FIG. 2D, sidewall oxidation film 209 as a dielectric film for insulating a gate is formed on and/or over the entire surface of semiconductor substrate 201 where the poly gate is formed. Sidewall oxidation film 209 is preferably formed at a thickness in a range between approximately 4 to 6 nm. Next, after forming sidewall oxidation film 209, an etching process is carried out using a preset pattern mask so that sidewall oxidation film 209 remains only on and/or over sidewalls of the poly gate and on an uppermost surface thereof.

As illustrated in example FIG. 2E, spacer nitride film 211 is formed on and/or over the entire surface of substrate 201 including sidewall oxidation film 209 by chemical vapor deposition (CVD). Spacer nitride film 211 is preferably formed at a thickness in a range between approximately 18 to 22 nm.

As illustrated in example FIG. 2F, after forming spacer nitride film 211, spacer 213 is formed on and/or over each sidewall of the poly gate by carrying out an etching process on spacer nitride film 211.

As illustrated in example FIG. 2G, portions of the uppermost surface of semiconductor substrate 201 is removed to a predetermined depth using the same etching mask used to form spacer 213. In accordance with embodiments, the predetermined depth may be in a range between approximately 18 to 22 nm. Substrate 201 may have a stepped portion including a first substrate portion upon which the poly gate is formed and a second substrate portion provided below the first substrate portion a distance equal to the predetermined depth.

As illustrated in example FIG. 2H, ion-doped oxide film 215 doped with ions of at least one of phosphorous (P) in case of N-MOS and boron (B) in case of P-MOS for a shallow junction is formed on and/or over the entire surface of substrate 201 including poly gate using a CVD method.

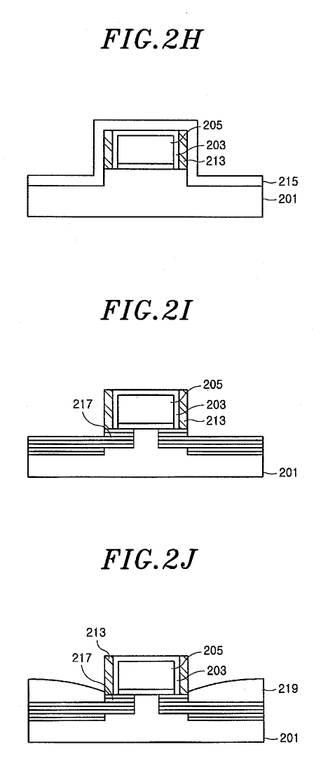

As illustrated in example FIG. 21, shallow junction 217 may then be formed on and/or over substrate 210 and under the poly gate and oxide film 215 is simultaneously removed by diffusing the dopant contained in oxide film 215 into portions of the first substrate portion and the second substrate portion of semiconductor substrate 201 by a thermal process. The thermal process is carried out in a range between approximately 25 to 35 minutes at a temperature in a range between approximately 800 to 1000° C.

As illustrated in example FIG. 2J, after forming shallow junction 217 and removing oxide film 215, source and drain regions 219 are formed on and/or over shallow junction 217 and contacting sidewalls of shallow junction 217 and spacer 213.

Embodiments can eliminate the cause of increase in leakage current and therefore suppress power increase in a highly integrated circuit by forming a shallow junction by use of a dopant-containing oxide film after etching a semiconductor substrate in source and drain regions. Furthermore, embodiments can maximize the integrity of an SRAM bit-cell size or the like and obtain a process allowance by minimizing a spacer width.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing a semiconductor device comprising:
forming a gate over a semiconductor substrate; and then
forming a first oxide film on sidewalls of the gate; and then
forming a spacer on sidewalls of the gate; and then
removing a portion of the semiconductor substrate to a predetermined depth by performing an etching process using the spacer as a mask and then forming a dopant-containing second oxide film over the semiconductor substrate, the first oxide film and the spacer; and then
forming a shallow junction in the semiconductor substrate by diffusing the dopant from the second oxide film into portions of the semiconductor substrate by performing a thermal process; and then
forming a source and drain region over the semiconductor substrate including the shallow junction.

2. The method of claim 1, wherein the first oxide film has a thickness in a range between approximately 4 to 6 nm.

3. The method of claim 1, wherein the nitride film has a thickness in a range between approximately 18 to 22 nm.

4. The method of claim 1, wherein the predetermined depth is in a range between approximately 18 to 22 nm.

5. The method of claim 1, wherein the dopant-containing second oxide film is formed using a CVD process.

6. The method of claim 1, wherein the dopant is phosphorous.

7. The method of claim 1, wherein the dopant is boron.

8. The method of claim 1, wherein the thermal process is carried out in a range between approximately 25 to 35 minutes at a temperature in a range between approximately 800 to 1000° C.

9. The method of claim 1, wherein the spacer is composed of a nitride material.

10. A semiconductor device comprising:
a polysilicon gate formed over a semiconductor substrate;
an oxide film formed over sidewalls of the polysilicon gate;
a spacer formed over sidewalls of the oxide film;
a shallow junction formed in the semiconductor substrate by diffusing a dopant into the semiconductor substrate; and
a source and a drain formed over the shallow junction.

11. The semiconductor device of claim 10, wherein the oxide film has a thickness in a range between approximately 4 nm to 6 nm.

12. The semiconductor device of claim 10, wherein the spacer is composed of a nitride material formed at thickness in a range between approximately 18 nm to 22 nm.

13. The semiconductor device of claim 10, wherein the predetermined depth is in a range between approximately 18 nm to 22 nm.

14. A method comprising:
forming a gate over a substrate; and then
forming a first oxide film over the substrate including uppermost surface and sidewalls of the gate; and then
forming a nitride spacer over sidewalls of the gate including the first oxide film; and then
forming a stepped portion of the substrate by removing portions of the substrate such that substrate includes a first substrate portion upon which the gate is formed and a second substrate portion provided laterally below the first substrate portion at a predetermined distance; and then
forming a doped second oxide film over the entire surface of the first and second portions of the substrate including the gate; and then
simultaneously forming a shallow junction under the gate and removing the doped second oxide film by performing a thermal process; and then
forming source and drain regions over the shallow junction.

15. The method of claim 14, wherein the source and drain regions contact the sidewalls of the shallow junction and the nitride spacer.

16. The method of claim 14, wherein the doped second oxide film is doped with phosphorous.

17. The method of claim 14, wherein the doped second oxide film is doped with boron.

18. The method of claim 14, wherein the thermal process is carried out in a range between approximately 25 to 35 minutes at a temperature in a range between approximately 800 to 1000° C.

19. The method of claim 14, wherein the predetermined distance is in a range between approximately 18 nm to 22 nm.

20. The method of claim 14, wherein simultaneously forming a shallow junction under the gate and removing the doped second oxide film comprises:
diffusing the dopant contained in the doped second oxide film into portions of the first substrate portion and the second substrate portion by performing the thermal process.
